(19) United States
(12) Patent Application Publication
(10) Pub. No.: US 2009/0321922 A1
(43) Pub. Date: Dec. 31, 2009

(54) SELF-HEALING THERMAL INTERFACE MATERIALS FOR SEMICONDUCTOR PACKAGES

(76) Inventors: Ravi Shankar, Chandler, AZ (US); Nachiket R. Raravikar, Chandler, AZ (US); Dingying Xu, Maricopa, AZ (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 12/164,960

(22) Filed: Jun. 30, 2008

(51) Int. Cl. H01L 23/34; H01L 21/00

(52) U.S. Cl. 257/706; 438/122; 257/E23.051

(57) ABSTRACT

A semiconductor package is described. The semiconductor package includes an internal housing and a semiconductor die coupled with the internal housing by a layer of self-healing thermal interface material.

### TECHNICAL FIELD

Embodiments of the invention are in the field of semiconductor packages and, in particular, interface materials for semiconductor packages.

### BACKGROUND

Today's consumer electronics market frequently demands complex functions requiring very intricate circuitry. Scaling to smaller and smaller fundamental building blocks, e.g. transistors, has enabled the incorporation of even more intricate circuitry on a single die with each progressive generation. On the other hand, although scaling is typically viewed as a reduction in size, the size of a particular semiconductor die may in fact be increased in order to include multi-functional components on a single die.

However, structural issue may arise when attempting to package larger scale semiconductor die in a semiconductor package. For example, the effect of differences in the coefficients of thermal expansion (CTE) between components used in a semiconductor package can lead to detrimental defects as a result of performing the semiconductor die packaging process. FIGS. 1A-1B illustrate cross-sectional views representing operations in a conventional semiconductor packaging process. Referring to FIG. 1A, a semiconductor die 102 is disposed on a substrate 104 and is bonded to a integrated heat spreader 106 by a thermal interface material 108 to form a semiconductor package 100. The bonding of integrated heat spreader 106 to semiconductor die 102 by thermal interface material 108 is usually performed by heating to temperatures much higher than room temperature, in order to cure thermal interface material 108. During the heating, some distortion of substrate 104 and, hence, semiconductor die 102, may occur as a result of CTE mismatch between substrate 104, semiconductor die 102 and integrated heat spreader 106, as depicted in FIG. 1A.

At the time of curing at an elevated temperature, thermal interface material 108 may conform to deformations caused by the CTE mismatch, as depicted in FIG. 1A. However, upon cooling semiconductor package 100 following the curing process, CTE mismatch may lead to even more severe deformation. Referring to FIG. 1B, upon cooling, semiconductor die 102 deforms to a greater extent than at the curing operation because semiconductor die 104 is now bonded to integrated heat spreader 106 by thermal interface material 108, e.g., semiconductor die 104 is fixed in place in relation to integrated heat spreader 106. This enhanced deformation resulting from CTE mismatch can lead to a delamination site 110 between thermal interface material 108 and semiconductor die 102 or can lead to a cohesive cracking site 112 within thermal interface material 108, where instances of both types of sites are depicted in FIG. 1B.

### BRIEF DESCRIPTION OF THE DRAWINGS

FIGS. 1A-1B illustrate cross-sectional views representing operations in a conventional semiconductor packaging process.

FIG. 2 depicts a plot showing the typical phase diagram of block co-polymers, in accordance with an embodiment of the present invention.

FIG. 3 illustrates a di-block co-polymer undergoing the ordered-disordered transition represented in FIG. 2.

FIG. 4 illustrates a cross-sectional view of a semiconductor package including a layer of self-healing thermal interface material, in accordance with an embodiment of the present invention.

FIGS. 5A-5C illustrate cross-sectional views representing operations in a semiconductor packaging process, in accordance with an embodiment of the present invention.

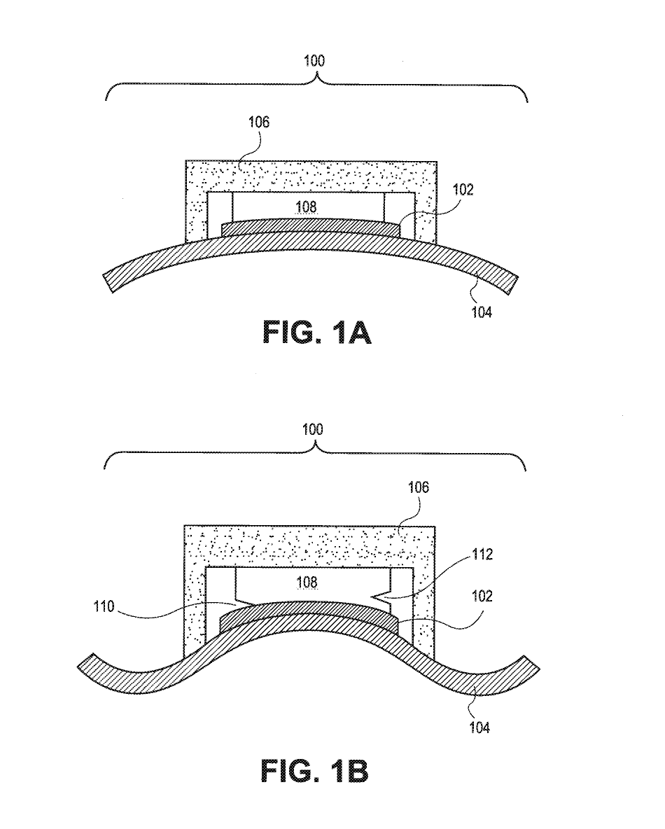

### DETAILED DESCRIPTION

Self-healing thermal interface materials for semiconductor packages are described. In the following description, numerous specific details are set forth, such as packaging architectures and material regimes, in order to provide a thorough understanding of embodiments of the present invention. It will be apparent to one skilled in the art that embodiments of the present invention may be practiced without these specific details. In other instances, well-known features, such as integrated circuit design layouts, are not described in detail in order to not unnecessarily obscure embodiments of the present invention. Furthermore, it is to be understood that the various embodiments shown in the Figures are illustrative representations and are not necessarily drawn to scale.

Disclosed herein are semiconductor packages that include a layer of self-healing thermal interface material. A semiconductor package may include an internal housing and a semiconductor die. In one embodiment, the semiconductor die is coupled with the internal housing by a layer of self-healing thermal interface material. A method for fabricating a semiconductor package may include incorporation of a layer of self-healing thermal interface material. In one embodiment, a substrate is provided. A semiconductor die is disposed above the substrate and a layer of self-healing thermal interface material is formed above the semiconductor die. An integrated heat spreader is disposed on the layer of self-healing thermal interface material. The substrate, the integrated heat spreader, the semiconductor die and the layer of self-healing thermal interface material are heated to a first temperature sufficient to bond the integrated heat spreader to the semiconductor die via the layer of self-healing thermal interface material. The layer of self-healing thermal interface material undergoes an order-disorder transition during the heating. The substrate, the integrated heat spreader, the semiconductor die and the layer of self-healing thermal interface material are then cooled to a second temperature, wherein the second temperature is less than the first temperature. The layer of self-healing thermal interface material undergoes a disorder-order transition during the cooling.

Exacerbated CTE mismatch issues in large form-factor semiconductor packages may be accommodated by incorporating a layer of self-healing thermal interface material for purposes of bonding within the semiconductor package. For example in accordance with an embodiment of the present invention, the CTE mismatch between an approximately 2 centimeters X 2 centimeters semiconductor die and other components included in the semiconductor package housing the semiconductor die is accommodated by incorporating a layer of self-healing thermal interface material. In one embodiment, the layer of self-healing thermal interface material is disposed between the semiconductor die and an integrated heat spreader. The layer of self-healing thermal interface material undergoes an order-disorder transition upon heating to bond the semiconductor die to the integrated heat spreader via the layer of self-healing thermal interface material. Then, upon cooling, the layer of self-healing thermal interface material undergoes a disorder-order transition, e.g. the order-disorder transition is reversible, allowing for CTE mismatch accommodation. Thus, a self-healing thermal interface material may take on a different shape than it had upon initial deposition or at a high temperature bonding operation. It is to be understood that embodiments of the present invention are not limited to large-form factor semiconductor die packaging. For example, in one embodiment, a layer of self-healing thermal interface material is used for packaging a semiconductor die having a dimension less than approximately 1 centimeter X 1 centimeter.

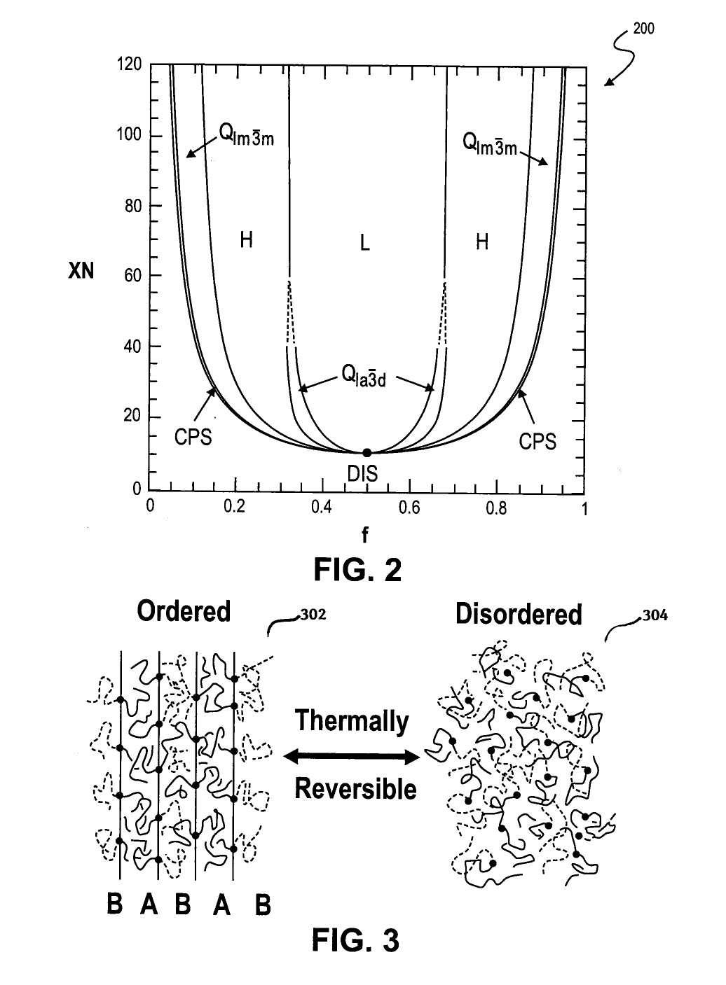

In accordance with an embodiment of the present invention, a layer of self-healing thermal interface material is a material such as, but not limited to, a thermoplastic elastomer or a thermoplastic elastomer gel. Such materials may be multi-functional polymeric materials that generally have the process tolerance of thermoplastics and the elasticity of vulcanized rubber and are therefore considered biphasic. For example in one embodiment, the layer of self-healing thermal interface material is a single macromolecule having discrete thermoplastic segments capable of forming rigid nanoscale domains or channels covalently bonded to rubbery segments that provide a soft matrix in which the rigid domains reside. Due to the covalent linkages between the chemically dissimilar segments, the rigid domains can form a three-dimensional network of physical cross-link sites. In one embodiment, the layer of self-healing thermal interface material is a block co-polymer. Block co-polymer phase behavior is primarily determined by three experimentally controllable factors: 1) the overall degree of polymerization, N, 2) the magnitude of the Flory-Huggins segment-segment interaction parameter, X, and 3) the volume fraction of type-A repeat units, f. The Flory-Huggins interaction parameter has strong temperature dependence X˜αT⁻¹+β, where α and β are constants for given values of f and N, and where α>0. FIG. 2 depicts a plot 200 showing the typical phase diagram of block co-polymers, in accordance with an embodiment of the present invention. Referring to plot 200, as the incompatibility (XN) decreases or temperature increases, block co-polymer ordered phases [e.g., H (hexagonal), L (lamellar), Qₗₘ₃ₘ (bcc spheres), CPS (close-packed spheres)] change to a DIS (disordered) phase. Referring again to plot 200, when a disordered phase is cooled down or incompatibility increases, it forms ordered phases once again. Thus, the material is “self-healing.” Accordingly, in an embodiment of the present invention, a layer of self-healing thermal interface material provides a thermally reversible avenue to inhibit the formation of delamination sites or cohesive cracking sites, as described below.

A layer of self-healing thermal interface material may undergo an order-disorder transition upon heating. FIG. 3 illustrates a di-block co-polymer undergoing the ordered-disordered transition represented in plot 200 of FIG. 2. Referring to FIG. 3, an ordered di-block co-polymer 302 includes repeating B segments and A segments. Upon heating, ordered di-block co-polymer 302 becomes a disordered polymer 304. In accordance with an embodiment of the present invention, the order-disorder transition is reversible upon cooling disordered polymer 304, as depicted in FIG. 3. A bonding temperature may be selected for packaging a semiconductor die with a layer of self-healing thermal interface material. In an embodiment, the bonding temperature is selected to be above the order-disorder transition temperature for the layer of self-healing thermal interface material. The layer of self-healing thermal interface material will take on any shape necessary to bond a semiconductor die to other components of a semiconductor package, e.g. an integrated heat spreader. However, in one embodiment, upon cooling, CTE mismatches within the semiconductor package change the shape and orientation of the various components of the semiconductor package to one another. Because the layer of self-healing thermal interface material is disordered, the layer can accommodate the CTE mismatch by changing its shape. Then, when the temperature falls below the order-disorder temperature for the layer of self-healing thermal interface material, the layer of self-healing thermal interface material becomes ordered with a shape appropriate for bonding without forming delamination sites or cohesive cracking sites. Thus, in accordance with an embodiment of the present invention, a layer of self-healing thermal interface material is used to inhibit delamination or cohesive cracking from occurring within a semiconductor package.

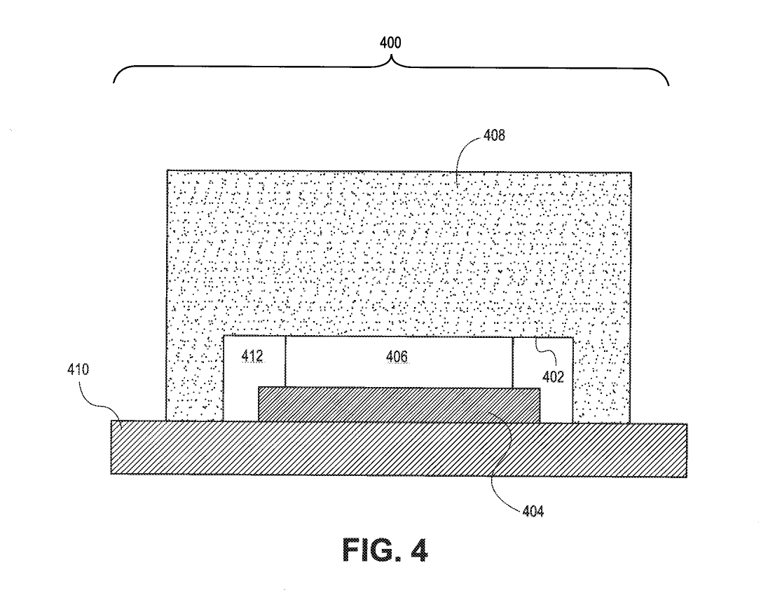

In an embodiment of the present invention, a semiconductor package includes a layer of self-healing thermal interface material. FIG. 4 illustrates a cross-sectional view of a semiconductor package 400 including a layer of self-healing thermal interface material, in accordance with an embodiment of the present invention.

Referring to FIG. 4, semiconductor package 400 includes an internal housing 402 and a semiconductor die 404 coupled with internal housing 402 by a layer of self-healing thermal interface material 406. In one embodiment, internal housing 402 is an inner wall of an integrated heat spreader 408, as depicted in FIG. 4. Semiconductor package 400 may also include a substrate 410, wherein integrated heat spreader 408 is disposed above and coupled with substrate 410, as depicted in FIG. 4. A cavity 412 is disposed between substrate 410 and integrated heat spreader 408. Semiconductor die 404 is disposed above substrate 410 and within cavity 412. In accordance with an embodiment of the present invention, the layer of self-healing thermal interface material 406 is disposed in cavity 412, between semiconductor die 404 and integrated heat spreader 408. In one embodiment, the layer of self-healing thermal interface material 406 bonds semiconductor die 404 to integrated heat spreader 408, as depicted in FIG. 4.

The layer of self-healing thermal interface material 406 may be composed of a material that undergoes a reversible order-disorder transition upon heating and subsequent cooling. In accordance with an embodiment of the present invention, the layer of self-healing thermal interface material 406 is polymeric, e.g., the layer of self-healing thermal interface material 406 exhibits long-range and discernable ordering of discrete units or building blocks. In one embodiment, the layer of self-healing thermal interface material 406 is composed of a material such as, but not limited to, a thermoplastic elastomer or a thermoplastic elastomer gel. In an embodiment, the layer of self-healing thermal interface material 406 is composed of a thermoplastic elastomer material such as, but not limited to, a di-block co-polymer, a tri-block co-polymer or a multi-block co-polymer. In an embodiment, the thermoplastic elastomer material is solvated. In an embodiment, the thermoplastic elastomer material is non-solvated. In another embodiment, the layer of self-healing thermal interface material 406 further includes conductive fillers, e.g., the layer of self-healing thermal interface material 406 is a composite. In an embodiment, the conductive fillers are metallic and are composed of a metal such as, but not limited to, aluminum, copper or nickel. In another embodiment, the conductive fillers are ceramic and are composed of a material such as, but not limited to, zinc oxide, alumina, boron nitride or aluminum nitride. In an embodiment, conductive fillers make up approximately 80%-approximately 90% of the volume of the layer of self-healing thermal interface material 406. In another embodiment, conductive fillers make up at most approximately 10% of the volume of the layer of self-healing thermal interface material 406. The thickness of the layer of self-healing thermal interface material 406 may be a thickness suitable to bond semiconductor die 404 to integrated heat spreader 408 while being able to accommodate an order-disorder shape change. In one embodiment, the thickness of the layer of self-healing thermal interface material 406 is approximately in the range of 25-125 microns.

In an exemplary embodiment, the layer of self-healing thermal interface material 406 is formed by mixing an oil and a tri-block co-polymer such as, but not limited to, styrene-b-(ethylene-co-butylene)-b-styrene at a predetermined concentration. In an embodiment, the oil and the tri-block co-polymer are further mixed with thermally conductive fillers in an organic solvent such as, but not limited to, chloroform, tetrahydrofuran (THF), toluene, DMF or a mixture thereof. In another exemplary embodiment, the layer of self-healing thermal interface material 406 is formed by dissolving tri-block/di-block co-polymers with thermally conductive fillers in an organic solvent such as, but not limited to, chloroform, tetrahydrofuran (THF), toluene or DMF. In yet another exemplary embodiment, the layer of self-healing thermal interface material 406 is formed by heating tri-block/di-block co-polymers above their order-disorder transition temperature, followed by melt-mixing without the use of solvents.

Semiconductor die 404 may be an individual semiconductor chip used in the electronics industry. In one embodiment, semiconductor die 404 is a microprocessor formed on a slice of mono-crystalline silicon. In another embodiment, semiconductor die 404 is a diode formed on a III-V material slice. Semiconductor die 404 may represent a platform of several units housed together, e.g., in one embodiment, semiconductor package 400 houses a multi-chip module. Semiconductor die 404 may have a surface having a micro-electronic integrated circuit formed thereon. In one embodiment, semiconductor die 404 has a surface including an array of CMOS transistors connected through a series of metal interconnects. In an embodiment, semiconductor die 404 has a thickness approximately in the range of 350-800 microns.

Integrated heat spreader 408 may be composed of a material or set of materials suitable for displacing heat from the surface of semiconductor die 404. In one embodiment, integrated heat spreader 408 is composed of a copper base plated with nickel metal. Substrate 410 may be composed of a material suitable for supporting semiconductor die 404 in semiconductor package 400. In one embodiment, substrate 410 is composed of a material having a CTE different from the CTE of integrated heat spreader 408.

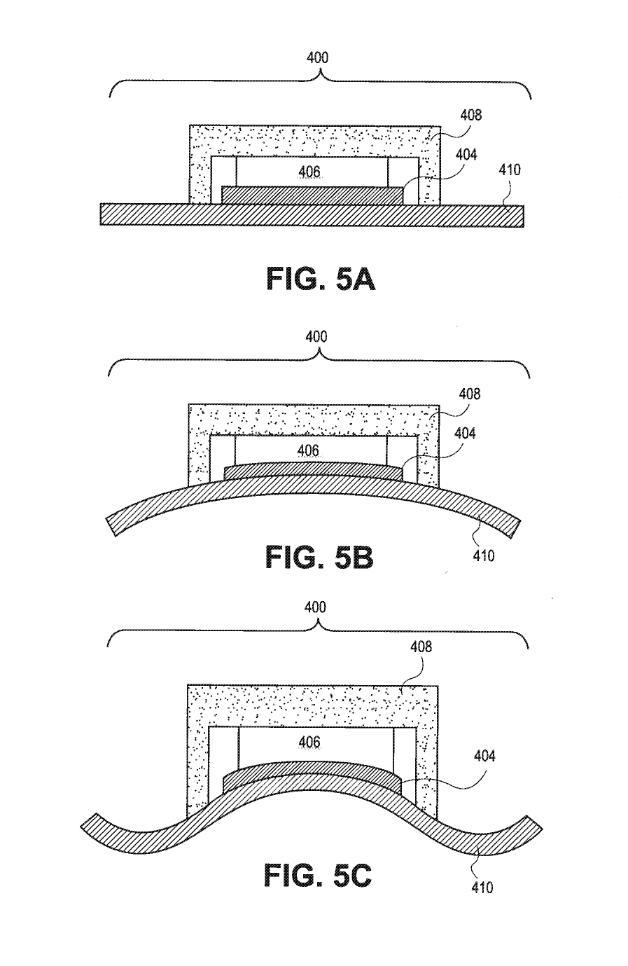

In another embodiment of the present invention, a method for fabricating a semiconductor package may include the incorporation of a layer of self-healing thermal interface material. FIGS. 5A-5C illustrate cross-sectional views representing operations in a semiconductor packaging process, in accordance with an embodiment of the present invention.

Referring to FIG. 5A, a substrate 410 of a semiconductor package 400 is provided. A semiconductor die 404 is disposed above substrate 410. A layer of self-healing thermal interface material 406 is formed above semiconductor die 404. An integrated heat spreader 408 is disposed on the layer of self-healing thermal interface material 406. Thus, in accordance with an embodiment of the present invention, the layer of self-healing thermal interface material 406 is formed directly between, and in contact with, semiconductor die 404 and integrated heat spreader 408. In an embodiment, in addition to the layer of self-healing thermal interface material 406, other components are included between semiconductor die 404 and integrated heat spreader 408.

Referring to FIG. 5B, substrate 410, integrated heat spreader 408, semiconductor die 404, and the layer of self-healing thermal interface material 406 are heated to a first temperature sufficient to bond integrated heat spreader 408 to semiconductor die 404 with the layer of self-healing thermal interface material 406. In accordance with an embodiment of the present invention, the layer of self-healing thermal interface material 406 undergoes an order-disorder transition during the heating. In one embodiment, the first temperature is a temperature approximately in the range of 110-165 degrees Celsius. In accordance with an embodiment of the present invention, some warping of the components of semiconductor package 400 occurs during heating as a result of CTE mismatch between the various components, as depicted in FIG. 5B.

Referring to FIG. 5C, substrate 410, integrated heat spreader 408, semiconductor die 404, and the layer of self-healing thermal interface material 406 are cooled to a second temperature, less than the first temperature. In one embodiment, the second temperature is a temperature approximately in the range of −55-125 degrees Celsius. In accordance with an embodiment of the present invention, warping of the components of semiconductor package 400 is exacerbated during the cooling as a result of CTE mismatch between the various components and because semiconductor die 404 is now bonded to integrated heat spreader 408 as a result of the previous heating operation. However, in one embodiment, the layer of self-healing thermal interface material 406 undergoes a disorder-order transition during the cooling. Thus, in an embodiment, the layer of self-healing thermal interface material 406 provides a thermally reversible avenue to inhibit the formation of delamination sites or cohesive cracking sites within semiconductor package 400 by accommodating shape and orientation changes of the components of semiconductor package 400 in response to CTE mismatch.

It is to be understood that embodiments of the present invention are not limited to using a layer of self-healing thermal interface material to accommodate CTE mismatch during a bonding process only. For example, in accordance with an embodiment of the present invention, a layer of self-healing thermal interface material is solvent-free and the bonding is carried out at a relatively low temperature, such as a temperature approximately in the range of 20-30 degrees Celsius. However, a semiconductor package fabricated in this way may still experience heating during operation of a semiconductor die housed therein. In one embodiment, a layer of self-healing thermal interface material is included in a semiconductor package in order to accommodate CTE mismatch events that occur during operation of a semiconductor die coupled with an integrated heat spreader by a layer of self-healing thermal interface material. Furthermore, in yet another embodiment of the present invention, if a delamination or cohesive cracking event does occur in the layer of self-healing thermal interface material during, e.g., fabrication of a semiconductor package, then the delamination or cohesive cracking site can be removed by heating the self-healing thermal interface material to a temperature greater than its order-disorder transition temperature.

Thus, semiconductor packages have been disclosed. In an embodiment, a semiconductor package includes an internal housing and a semiconductor die coupled with the internal housing by a layer of self-healing thermal interface material. In another embodiment, a semiconductor package includes a substrate and an integrated heat spreader disposed above and coupled with the substrate. A cavity is disposed between the substrate and the integrated heat spreader. A semiconductor die is disposed above the substrate and in the cavity. A layer of self-healing thermal interface material is disposed in the cavity between the semiconductor die and the integrated heat spreader, wherein the layer of self-healing thermal interface material bonds the semiconductor die to the integrated heat spreader. In another embodiment, a method for fabricating a semiconductor package including a layer of self-healing thermal interface material is provided.

1.-12. (canceled)

13. A method for fabricating a semiconductor package, comprising:
providing a substrate;
disposing a semiconductor die above said substrate;
forming a layer of self healing thermal interface material above said semiconductor die;
disposing an integrated heat spreader on said layer of self-healing thermal interface material;
heating said substrate, said integrated heat spreader, said semiconductor die and said layer of self healing thermal interface material to a first temperature sufficient to bond said integrated heat spreader to said semiconductor die with said layer of self-healing thermal interface material, wherein said layer of self-healing thermal interface material undergoes an order-disorder transition during the heating; and
cooling said substrate, said integrated heat spreader, said semiconductor die and said layer of self healing thermal interface material to a second temperature, wherein said second temperature is less than said first temperature, and wherein said layer of self-healing thermal interface material undergoes a disorder-order transition during the cooling.

14. The method of claim 13, wherein said first temperature is a temperature approximately in the range of 110-165 degrees Celsius.

15. The method of claim 13, wherein said second temperature is a temperature approximately in the range of −55-125 degrees Celsius.

16. The method of claim 13, wherein forming said layer of self-healing thermal interface material comprises using a polymeric material.

17. The method of claim 16, wherein forming said layer of self-healing thermal interface material comprises using a material selected from the group consisting of a thermoplastic elastomer and a thermoplastic elastomer gel.

18. The method of claim 17, wherein forming said self-healing thermal interface material comprises using a thermoplastic elastomer material selected from the group consisting of a di-block co-polymer, a tri-block co-polymer, and a multi-block co-polymer.

19. The method of claim 18, wherein using said thermoplastic elastomer material comprises using a solvated thermoplastic elastomer material.

20. The method of claim 17, wherein forming said self-healing thermal interface material further comprises using conductive fillers.
